(19) United States
(12) Patent Application Publication
(10) Pub. No.: US 2016/0299454 A1
(43) Pub. Date: Oct. 13, 2016

(54) LIGHT EMITTER, IMAGE FORMATION SYSTEM, AND EXPOSURE UNIT

(71) Applicant: CANON KABUSHIKI KAISHA, Tokyo (JP)

(72) Inventors: Satoru Shiobara, Funabashi-shi (JP); Ryuji Ishii, Yokohama-shi (JP); Koji Ishizuya, Kawasaki-shi (JP); Yojiro Matsuda, Kawasaki-shi (JP)

(21) Appl. No.: 15/090,508

(22) Filed: Apr. 4, 2016

(30) Foreign Application Priority Data
Apr. 8, 2015 (JP) 2015-079478
May 26, 2015 (JP) 2015-106772

(51) Int. Cl. B41J 2/385

(52) U.S. Cl. CPC G03G 15/04036; H04N 1/04; H04N 1/02805; H04N 1/0282; G06K 15/12; H01L 51/5246; H01L 27/3276; H01L 51/5253; H01L 2251/303; H01L 2251/301

(57) ABSTRACT

A light emitter includes an elongated substrate and a plurality of emission elements on the substrate. The emission elements include a first electrode, an organic layer, and a second electrode in this order from the substrate side. The organic layer stretches over one of the emission elements and a next one in the longitudinal direction of the substrate. The light emitter further has a plurality of projections on the substrate. Each of the projections is adjacent to each of the emission elements in the transverse direction of the substrate. The emission elements are located between one of the projections and another. The projections are higher than the second electrode with respect to the principal surface of the substrate. The projections and the second electrode are spaced from each other.

### BACKGROUND OF THE INVENTION

1. Field of the Invention

The present invention relates to a light emitter that includes an organic electroluminescent device and to an image formation system and an exposure unit in which such a light emitter is used.

2. Description of the Related Art

Printers with laser scanners, which are printers based on the technology of electrophotography, have gained widespread use. Common laser beam printers have a scanner with which light emitted from a laser source is scanned over a photosensitive element to make this element exposed to the light. This laser scanner, because of its structure, cannot be easily reduced in size.

Meanwhile, researchers have been studying laser beam printers that use an elongated light source for exposure (an elongated exposure light source) including an array of light-emitting devices to make a photosensitive element exposed. Allowing for the use of a smaller light source unit, this approach is effective in miniaturizing printers. Organic electroluminescent (EL) devices in particular, which are low power consumption light-emitting devices that can be densely arranged, can be used in light emitters for light source units of printers.

Organic EL devices have a pair of electrodes and an organic layer between the electrodes. Carriers injected from the pair of electrodes recombine in the organic layer, producing excitons. When the excitons return to the ground state, light is emitted.

Organic EL devices are promising light-emitting devices, but as known, they have their excellent properties affected when exposed to moisture. This means that the light-emitting properties of an organic EL device can be maintained by protecting the device from the entry of moisture during production and after completion.

Japanese Patent Laid-Open No. 2010-280066 describes the use of an organic EL device as an exposure section of an image formation system. This organic EL device has a substrate and an organic layer formed using a coating technique. There are walls on the substrate to prevent the coating liquid, in which an organic compound is dissolved, from flowing beyond the edge of the substrate. The device further has an upper electrode, which is continuous and stretches over the walls.

As a consequence of having an upper electrode stretching over the walls, however, this organic EL device may suffer from defects in the upper electrode or a thin-film seal optionally provided on the upper electrode if there is any contaminant on the walls. Such defects in a seal or the upper electrode provide pathways for moisture to penetrate, thereby causing the properties of the organic EL device to be affected.

### SUMMARY OF THE INVENTION

An aspect of the invention provides a highly reliable light emitter. This light emitter has projections and an upper electrode spaced from each other, and this structure limits the formation of ways in for moisture or other contaminants to reach the organic EL devices in the light emitter.

To be more specific, an aspect of the invention is a light emitter that includes an elongated substrate and a plurality of emission elements on the substrate. The emission elements include a first electrode, an organic layer, and a second electrode in this order from the substrate side. The organic layer stretches over one of the emission elements and a next one in the longitudinal direction of the substrate. The light emitter further has a plurality of projections on the substrate. Each of the projections is adjacent to each of the emission elements in the transverse direction of the substrate. The emission elements are located between one of the projections and another. The projections are higher than the second electrode with respect to the principal surface of the substrate. The projections and the second electrode are spaced from each other.

Further features of the present invention will become apparent from the following description of exemplary embodiments with reference to the attached drawings.

### BRIEF DESCRIPTION OF THE DRAWINGS

FIGS. 1A and 1B are schematics of some examples of light emitters according to an aspect of the invention.

FIG. 2 is a schematic cross section taken along line II-II in FIG. 1A.

FIGS. 3A to 3C are schematics of some examples of arrangement patterns for emission elements in a light emitter according to an aspect of the invention.

FIG. 4 is a schematic of an example of a structure of a light emitter according to an aspect of the invention.

FIG. 5 is a schematic of an example of a structure of a light emitter according to an aspect of the invention.

FIGS. 6A to 6E are schematics of an example of a process for the production of a light emitter according to an aspect of the invention.

FIGS. 7A to 7C are schematics of the flexural relationship between a substrate and a mask during the production of a light emitter according to an aspect of the invention.

FIG. 8 is a diagram illustrating an example of a batch production of light emitters according to an aspect of the invention on a mother glass substrate.

FIG. 9 is an enlarged view of area IX in FIG. 8.

FIG. 10 is a diagram illustrating another example of a method for batch production of a light emitter according to an aspect of the invention on a mother glass substrate.

FIG. 11 is an enlarged view of area XI in FIG. 10.

FIG. 12 is a diagram illustrating another example of a light emitter according to an aspect of the invention.

FIG. 13 is a schematic cross section of an example of a sealing structure for a light emitter according to an aspect of the invention.

FIG. 14 is a schematic of an example of an image formation system that has a light emitter according to an aspect of the invention.

FIGS. 15A and 15B are schematic top views of specific examples of exposure light sources (exposure mechanisms) that can be used in the image formation system illustrated in FIG. 14.

FIG. 15C is a schematic of a specific example of a photosensitive element that can be used in the image formation system illustrated in FIG. 14.

### DESCRIPTION OF THE EMBODIMENTS

An aspect of the invention is a light emitter that includes a substrate and a plurality of emission elements on the substrate.

The emission elements include a first electrode, an organic layer, and a second electrode in this order from the substrate side.

The organic layer stretches over one of the emission elements and a next one in the longitudinal direction of the substrate.

The light emitter further has a plurality of projections on the substrate. The projections are adjacent to the emission elements, on a one-by-one basis, in the transverse direction of the substrate.

The emission elements are located between one of the projections and another.

The projections are higher than the second electrode with respect to the principal surface of the substrate.

The projections and the second electrode are spaced from each other. The projections protect the organic EL devices from external contact.

The light emitter according to an aspect of the invention has projections higher than the second electrode with respect to the principal surface of the substrate. This means that the projections are taller than the second electrode. This structure ensures that the projections come into contact with external components first, preceding the second electrode, thereby making the projections more likely to catch contaminants than the second electrode is. These projections and the second electrode, or the organic EL devices, are spaced from each other. Even if any contaminant on the projections forms pathways for moisture to penetrate, this structure limits the formation of pathways through which the moisture could reach the organic EL devices.

An example of a situation where the projections catch a contaminant is when the projections come into contact with a mask for deposition, for example.

The substrate has two different directions: first and second directions. The substrate is described as elongated when its length in the first direction is greater than its length in the second direction. The first and second directions may be perpendicular to each other. The first and second directions of an elongated substrate may be referred to as longitudinal and transverse directions, respectively.

An elongated substrate may bend if the substrate is held only at its longitudinal ends. In an aspect of the invention, the projections provided in the light emitter can be used to hold the substrate in addition to the longitudinal ends of the substrate.

The reduced bending of the substrate, as a result, allows the user to form the organic layer with good characteristics, even by vapor deposition for example.

The projections according to an aspect of the invention can be made from inorganic or resin materials. Inorganic projections can be obtained by working silicon oxide or silicon nitride using dry etching, photolithography, or similar. Resin projections can be obtained by curing a photosensitive resin, such as a photoresist.

The height of the projections in relation to the top of the substrate can be 1 μm or more, preferably 2 μm or more and 10 μm or less.

### Organic Light Emitter

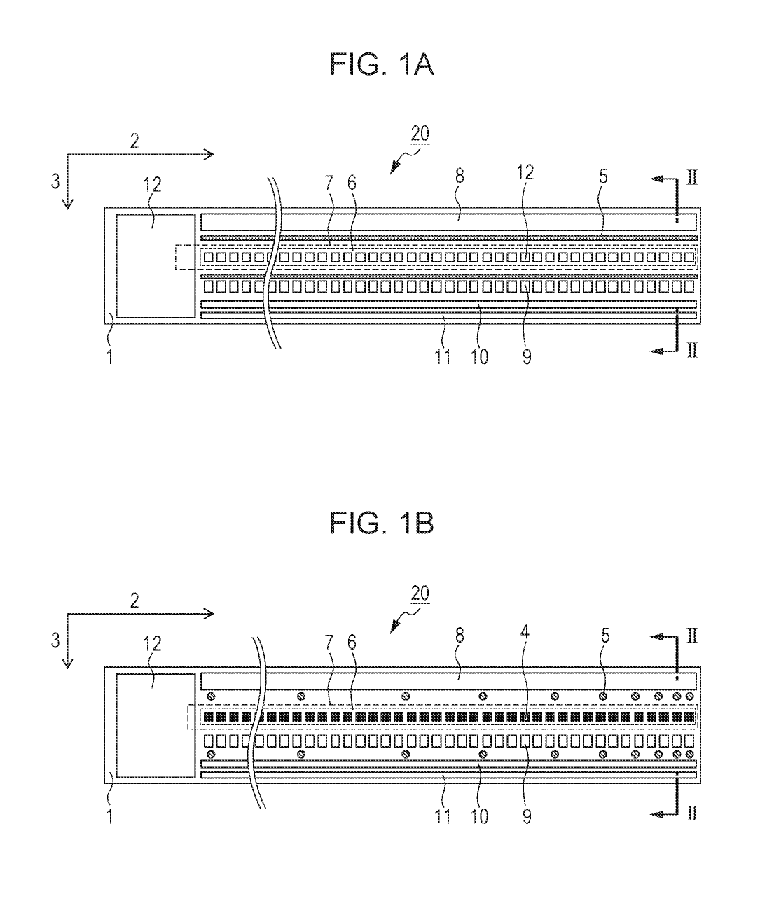

FIG. 1A is a schematic of a light emitter according to an aspect of the invention in the direction perpendicular to the principal surface of the substrate. The elongated substrate 1 has a longitudinal direction 2 and a transverse direction 3. The light emitter has emission elements 4 and projections 5 on the substrate 1, with the emission elements and the projections spaced from each other. The light emitter also has an organic layer 6 and a second electrode 7 between one projection and another. A data line 8 extends along a transverse end of the substrate, and there are pixel circuits 9, a power line 10, and a scanning circuit 11 along the other transverse end. A bonding pad 12 is present at one of the longitudinal ends of the substrate. Other arrangements are also possible.

Although the projections 5 in FIG. 1A look like continuous walls extending in the longitudinal direction of the substrate, segmented projections can also be used.

FIG. 1B illustrates another embodiment of a light emitter according to an aspect of the invention. As can be seen from FIG. 1B, the projections according to an aspect of the invention may be at irregular intervals. In this embodiment, the spacing between two adjacent projections becomes narrower toward the right end of the drawing. This arrangement ensures efficient contact between the projections and external components.

In this embodiment, the data line 8, the organic layer 6, and the scanning circuit 11 are arranged in this order in the transverse direction of the substrate. In other words, the organic layer is located between the data line and the scanning circuit. This arrangement, in which the organic layer 6 is located between the two components and therefore is away from the transverse ends of the substrate, effectively prevents the entry of external moisture. The data line and other wire lines, or collectively the wiring, may be all along one side of the substrate.

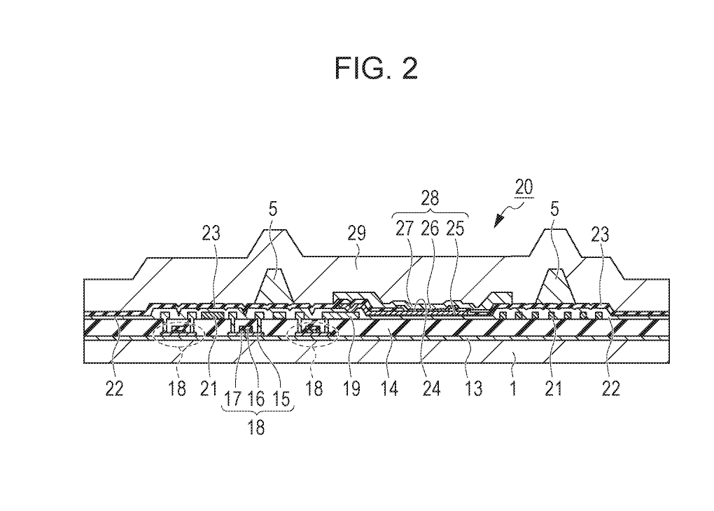

FIG. 2 is a schematic cross section taken along line II-II in FIG. 1A. The light emitter 20 has an undercoat 13 and an interlayer dielectric 14 on the substrate 3. There are thin-film transistors 18 on the undercoat 13, each including a channel 15, a gate dielectric 16, and a gate electrode 17. The thin-film transistors (TFTs) 18 are switching devices that constitute drive circuits such as the pixel circuits 9 and the scanning circuit 11.

The light emitter 20 further has source/drain electrodes 19 and metal wiring 21 on the interlayer dielectric 14. The source/drain electrodes are electrically coupled to the channel 15 and the gate electrode 17 of the TFTs 18 via holes created in the interlayer dielectric 14. The metal wiring 21 provides the power line 10 and the data line 8.

On the interlayer dielectric 14, on which there exist the source/drain electrodes 19 and the metal wiring 21, the light emitter 20 has a passivator 22 made of silicon oxide, silicon nitride, or any other inorganic insulator as a protection for the metal wiring.

A first electrode 25 of an organic EL device 28 is located on the interlayer dielectric 14, coupled to a source/drain electrode 19. The first electrode may also be referred to as the lower electrode. The first electrode is covered with a pixel separator 23 at its ends to prevent short circuits between the first electrode and a second electrode 27. An organic layer 26 is located between the first electrode 25 and the second electrode 27. The pixel separator 23 has an opening 24, in which the organic layer 26 is in contact with the first electrode 25. The second electrode 27 is spaced from the projections 5. The second electrode may also be referred to as the upper electrode.

There is also a seal 29 made of an inorganic material, covering the second electrode and the projections.

The substrate can be, for example, a glass substrate or a silicon substrate. A flexible substrate can also be used. Even if a flexible substrate is used, the projections allow the user to perform vapor deposition without contact of organic EL devices with the masks for deposition.

The undercoat and the interlayer dielectric are layers of inorganic insulators, such as silicon oxide and silicon nitride.

At least one of the first and second electrodes is transparent or translucent. The term translucent means that the material has a transmittance of 50% or more. The other electrode may be a reflective electrode.

Transparent electrodes can be made from materials such as indium tin oxide and indium zinc oxide. Translucent electrodes can be layers of materials such as aluminum and silver having an appropriate thickness, e.g., 20 nm or more and 30 nm or less. Translucent electrodes can be made from materials highly reflective to the visible spectrum. Besides pure aluminum and silver, such electrodes can also be made from their alloys or be multilayer structures containing these metals, preferably an Ag—Mg alloy or multilayer structure if silver is used.

The pixel separator is a layer that prevents short circuits between the first and second electrodes. The organic layer interposed between the first and second electrodes are not thick enough to prevent these electrodes from short-circuiting. Thus, the pixel separator is provided.

The opening in the pixel separator defines the plane where the first electrode and the organic layer come into contact. In other words, emission regions are defined by the pixel separator.

The pixel separator can be made from organic or inorganic materials, preferably inorganic materials. Examples of materials for organic pixel separators include resins such as polyimide. Examples of materials for inorganic pixel separators include silicon oxide and silicon nitride.

The organic layer includes an emission layer. Although the organic layer in FIG. 2 looks like a single layer, it may be composed of multiple layers. Examples of layers a multilayer organic layer can have in addition to the emission layer include a hole injection layer, a hole transport layer, an electron blocking layer, a hole blocking layer, an electron transport layer, and an electron injection layer. The range of thicknesses of the organic layer is approximately from 50 nm to 300 nm. The limits vary according to the optical interference design used.

The seal is a layer of an inorganic material. Specific examples of materials include silicon oxide, silicon nitride, silicon oxynitride, and aluminum oxides. Silicon oxide, silicon nitride, silicon oxynitride can be formed into a layer by sputtering or CVD, and aluminum oxides can be formed into a layer by ALD (atomic layer deposition). A water permeability of 10⁻⁶ g/m²·day or less provides sufficient tightness to the seal. The thickness of the seal is not limited. A thickness of 2 μm or more ensures sufficient tightness.

The light emitter may have a second seal such as a glass cap over a seal 29 with a desired thickness as a tentative sealing structure.

The seal 29 extends over the entire surface of the substrate. The bonding pad 12 is exposed in a separate operation and then is connected to the outside.

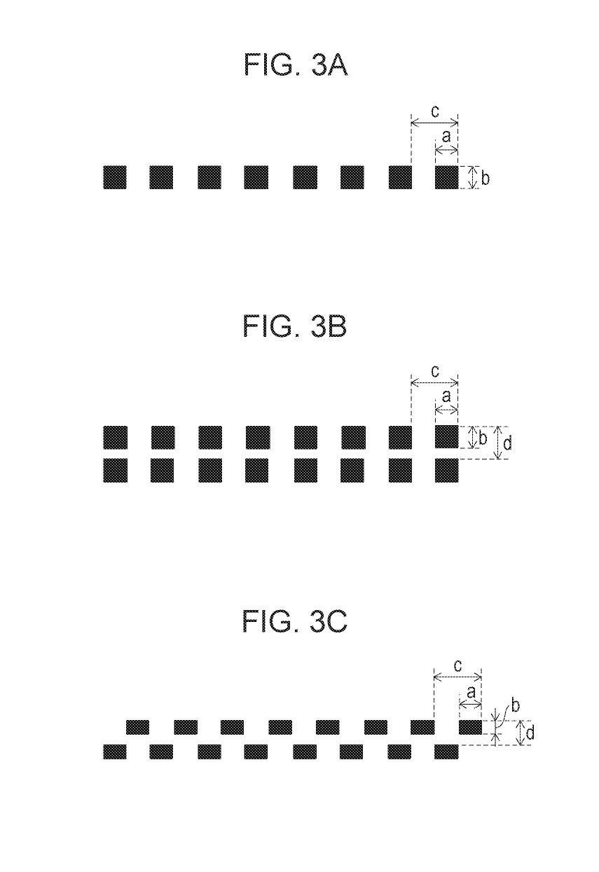

FIGS. 3A, 3B, and 3C illustrate some arrangement patterns for emission elements. A light emitter according to an aspect of the invention has multiple emission elements, optionally in an array of n rows and m columns (n≦4, 100≦m).

In FIG. 3A, multiple emission elements are arranged in a row. FIG. 3B illustrates an example where multiple emission elements are arranged in multiple rows. In FIG. 3B, there are two rows of emission elements. FIG. 3C illustrates an arrangement where two rows of emission elements are staggered in relation to one another. The staggered arrangement can also be described as an arrangement where in a first row of the multiple rows, the emission elements are spaced from each other in the direction of the rows, and in another row, the emission elements are at the positions where the spaces between one emission element and another are in the first row.

An example of a light emitter that uses the arrangement pattern illustrated in FIG. 3A is a linear emitter in which 2506 emission elements are arranged in a row. When the size a×b and pitch c of the emission elements are 42.3 μm×42.3 μm and 84.6 μm, respectively, the width of exposure is 212 mm (84.6 μm×2506 emission elements). The elongated substrate of this light emitter has longitudinal and transverse lengths of 219 mm and 4.7 mm, respectively. An elongated substrate according to an aspect of the invention may have a transverse length of 10 mm or less, preferably 1 mm or more and 10 mm or less. Shorter transverse lengths allow more light emitters to be produced from a single glass substrate.

The light emitter can also be a linear emitter in which emission elements are arranged in an array of 2 rows and 2506 columns as illustrated in FIG. 3B. When the size a×b, longitudinal pitch c, and transverse pitch d of the emission elements are 42.3 μm×42.3 μm, 84.6 μm, and 67.7 μm, respectively, the width of exposure is 212 mm (84.6 μm×2506 emission elements).

Alternatively, the emission elements may zigzag in a staggered pattern along the direction of columns as in FIG. 3C. In this pattern, emission elements can be arranged more densely in the direction of columns than in such a pattern as that of FIG. 3B. When the size a×b, longitudinal pitch c, and transverse pitch d of the emission elements are 42.3 μm×25.4 μm, 84.6 μm, and 50.8 μm, respectively, the width of exposure is 212 mm (42.3 μm×5012 emission elements).

### Other Embodiments of Projections

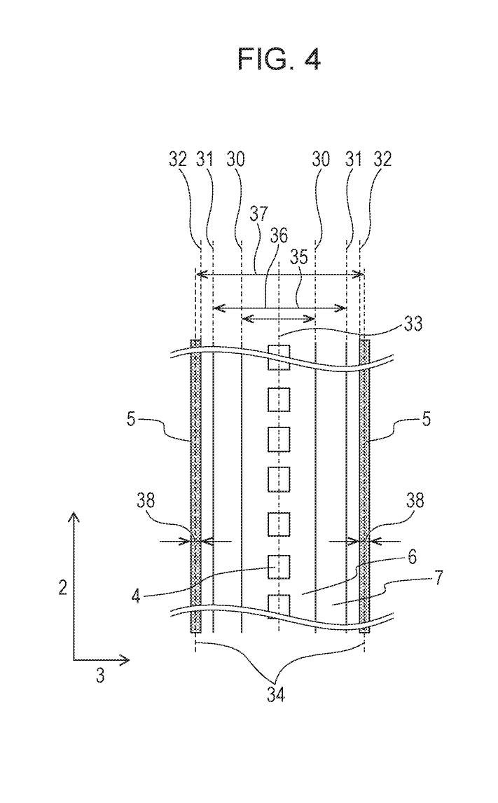

FIG. 4 illustrates a light emitter according to an aspect of the invention, excluding its peripheral edge. FIG. 4 includes some pairs of transverse ends: transverse ends of the organic layer (organic layer sides 30), transverse ends of the second electrode (second electrode sides 31), and transverse ends of the projections (projection sides 32). The drawing also illustrates the middle line of the substrate (substrate midline 33) and that of the projections (projection midlines 34). There are also some widths in the drawings: the transverse width of the organic layer (organic layer width 35), the transverse width of the second electrode (second electrode width 36), the distance between the projection midlines (projection pitch 37), and the transverse width of the projections (projection width 38). In light emitters according to an aspect of the invention, the projections are spaced from the second electrode. For the distance, formula (1) below may hold.

Projection pitch 37−Projection width 38−Second electrode width 36≧105 μm (1)

The projection pitch 37 is the sum of the projection width, the total width of the spaces, and the second electrode width. Formula (1) means that the total transverse length of the spaces that exist between one projection and the other, which is located across the organic layer, is 105 μm or more. Such a design ensures the second electrode and the projections remain spaced during the process of vapor deposition including deposition mask patterning.

As a result, the second electrode and the projections are spaced reliably in actual production, where positional variations can occur because of inaccurate alignment of substrates and masks.

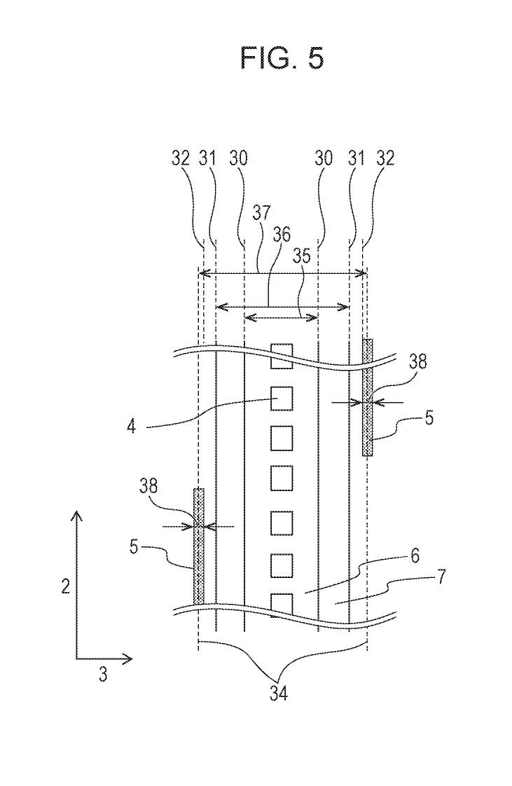

FIG. 5 illustrates a light emitter with a different arrangement pattern for projections. In the same way as in FIG. 4, the drawing excludes the peripheral edge of the light emitter. Satisfying the relationship in formula (1) is still effective even when the projections are arranged as in FIG. 5. The definitions of the specific distances are as illustrated in FIG. 5. To be more specific, the projection pitch is estimated at the point on the extension of a projection where the projection is the closest to the other.

Given the fact that most contaminants are particles with diameters smaller than 1 μm, the distance between a projection and the second electrode in the transverse direction of the substrate can be 2 μm or more.

The projections 5 may have any shape for the purpose of the protection of the emission elements 4. Strip-shaped projections, preferably non-segmented ones, have the ability to serve as a seamless protector.

The projections may have any longitudinal length. The projections may be longer than the emission elements in the longitudinal direction of the substrate, preferably longer than the organic layer, more preferably than the second electrode covering the organic layer. This ensures that any flaws due to rubbing or similar are substantially confined to the outside of the second electrode, limiting the formation of pathways that moisture can reach the organic EL devices through.

### Production of an Organic Light Emitter

The following describes the production of an organic light emitter according to an aspect of the invention. The production of an organic light emitter according to an aspect of the invention includes at least the following production processes:

(A) providing a pixel separator, which defines emission regions, on a first electrode;

(B) providing projections on the pixel separator;

(C) forming an organic layer on the first electrode;

(D) covering the organic layer with a second electrode; and

(E) providing a seal to cover the second electrode.

In this aspect of the invention, the second electrode and the projections are spaced from each other, preferably satisfying the relationship below.

Projection pitch 37−Projection width 38−Second electrode width 36≧105 μm (1)

This limits the formation of ways in for moisture that occurs in the course of producing the light emitter when the substrate comes into contact with a patterning mask and catches any contaminant on the projections during vacuum deposition. As a result, a highly reliable organic light emitter is obtained.

### (1) First Production Method

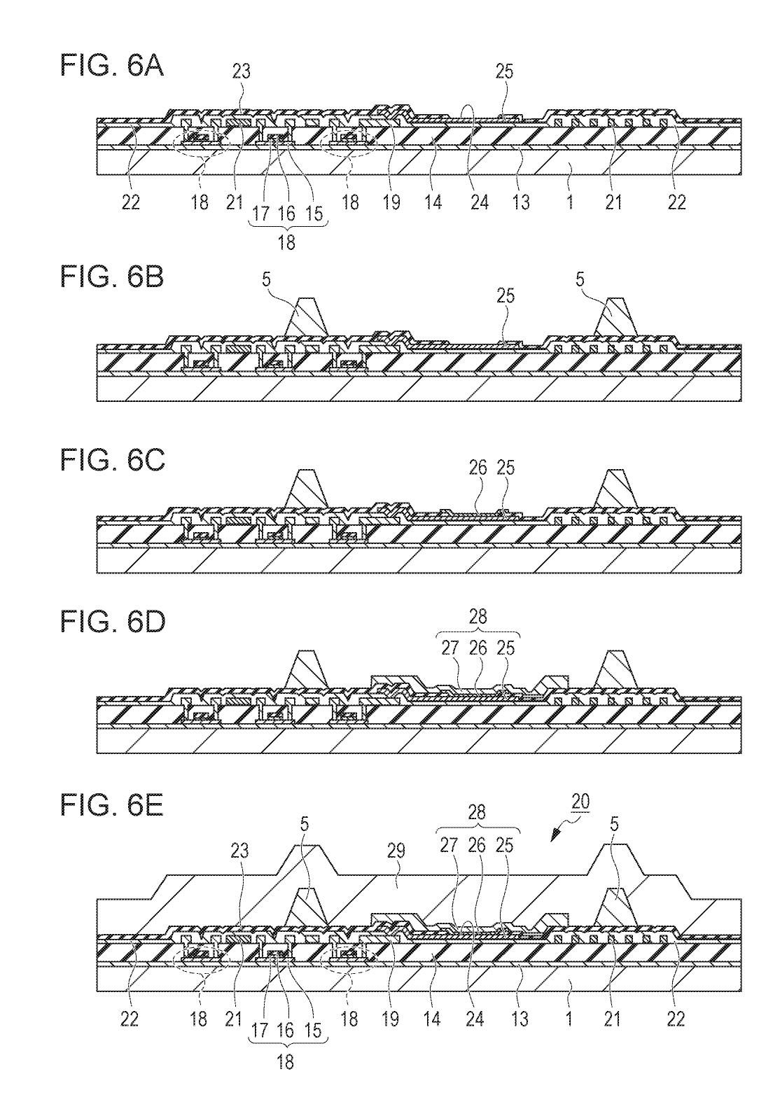

This section describes a first production method. FIGS. 6A to 6E are schematic cross sections illustrating a first embodiment of a method for the production of an organic light emitter according to an aspect of the invention.

### 1) Undercoating to the Formation of a Pixel Separator (FIG. 6A)

An undercoat 13 as a layer of an inorganic insulator, such as silicon oxide or silicon nitride, is formed on a substrate 3, for example a glass substrate, using CVD or similar.

TFTs 18 including a channel 15, a gate dielectric 16, and a gate electrode 17 are formed on the undercoat 13 in the same way as in the known production of TFTs.

An interlayer dielectric 14 as a layer of an inorganic insulator, such as silicon oxide or silicon nitride, is formed on the undercoat 13 with the TFTs 18 thereon using CVD or similar.

The interlayer dielectric 14 is perforated with holes using photolithography and dry etching to expose the electrodes of the TFTs 18. Components including source/drain electrodes 19 and metal wiring 21 are then formed. The source/drain electrodes 19 are coupled to the TFTs 18 via the holes.

A passivator 22 as a layer of an inorganic insulator, such as silicon oxide or silicon nitride, is formed on the interlayer dielectric 14 with the source/drain electrodes 19, the metal wiring 21, and other components thereon using CVD or similar.

The passivator 22 is perforated with holes using photolithography and dry etching to expose the source/drain electrodes 19. A first electrode 25 is then formed and coupled to the source/drain electrodes 19 via the holes.

After the first electrode 25 has been formed, a pixel separator 23 as a layer of an inorganic insulator, such as silicon oxide or silicon nitride, is formed using CVD or similar.

The pixel separator 23 is patterned using photolithography and dry etching to create openings 24 that define emission regions.

### 2) Formation of Projections on the Pixel Separator (FIG. 6B)

The pixel separator 23 is coated with a photosensitive resin material, such as polyacrylate or polyimide, using spin coating or similar. The coating of the photosensitive resin material is photolithographically patterned to form projections 5. This coating for the formation of the projections 5 according to an aspect of the invention needs to be thick enough that the projections 5 will protrude in the direction perpendicular to the surface of the substrate in relation to the second electrode 27 (described hereinafter). Resin materials can be formed into a thick film with relative ease.

### 3) Formation of an Organic Layer (FIG. 6C)

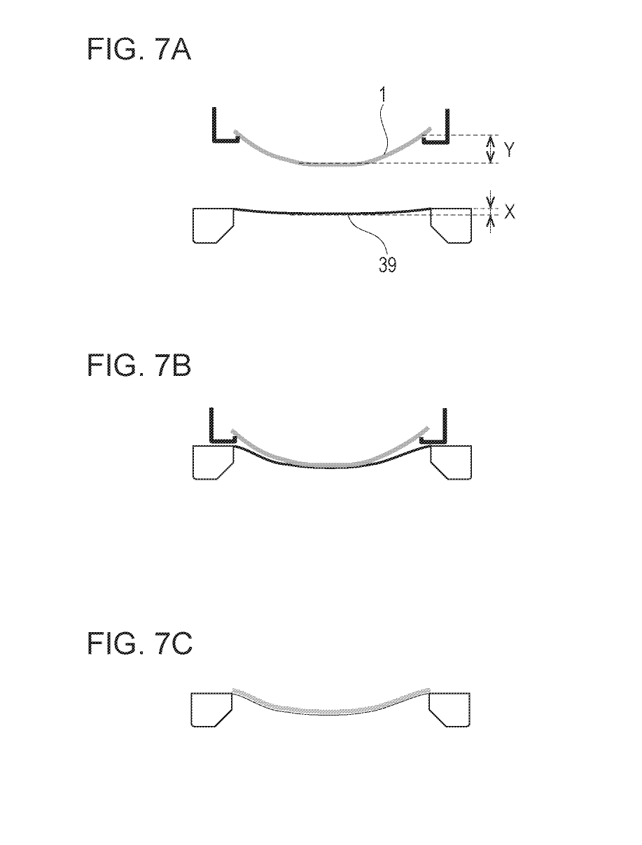

An organic layer 26 is formed to cover the exposed area, in the opening 24 created in the pixel separator 23, of the first electrode 25 through vapor deposition using a mask. The organic layer 26 has an emission layer that contains a light-emitting material, and may optionally have other layers such as a hole transport layer and an electron transport layer. Superposing the substrate 1 and the mask on one another as illustrated in FIGS. 7A to 7C before the formation of the organic layer 26 leads to site-selective formation of the organic layer.

### 4) Formation of an Upper Electrode (FIG. 6D)

A second electrode 27 is formed on the organic layer 26 and the pixel separator 23. The second electrode 27 is a metal film, such as one made from aluminum, silver, or magnesium or an alloy of these metals, formed through sputtering or vapor deposition using a mask. The organic layer 26 is covered with the second electrode 27. In this way, organic EL devices 28 that include the first electrode 25, the organic layer 26, and the second electrode 27 are formed.

Light emitters produced in this embodiment may have the bottom emission structure, in which light is taken out from the substrate side, or the top emission structure, in which light is taken out from the opposite side. When the organic EL devices 28 are bottom emission devices, the first electrode 25 is made from a transparent electrode material, such as ITO, and the second electrode 27 from a reflective electrode material, such as aluminum. When the organic EL devices 28 are top emission devices, the first electrode 25 is made from a reflective electrode material, and the second electrode 27 is made from a transparent electrode material.

### 5) Formation of a Thin-Film Seal (FIG. 6E)

A seal 29 as a layer of silicon nitride, silicon oxide, or similar is formed on the entire surface using sputtering, CVD, or similar. When the organic EL devices are bottom emission devices, the seal 29 does not need to be permeable to light. When the organic EL devices are top emission devices, the seal 29 needs to be permeable to light because the light the organic EL devices 28 generate is taken out on the seal 29 side.

When manufacturing elongated exposure light sources in which organic EL devices are arranged in a row, a possible way to reduce the cost is batch production of multiple exposure light sources on a single mother glass. For example, it is possible to produce 138 elongated exposure light sources (219 mm×4.7 mm) in a batch on a second-generation mother glass (460 mm×365 mm) if an array of 69 rows and 2 columns is used. The inventors, however, have found through research that batch production of multiple elongated exposure light sources on a large mother glass substrate suffers from the following disadvantage at the formation of the organic layer 26 and the second electrode 27.

FIGS. 7A to 7C are schematics of a process of superposing a substrate 1 and a mask 39 for deposition while keeping their alignment.

As illustrated in FIG. 7A, the substrate and the mask bend under their own weight. The amount of this self-weight flexure increases with increasing area of the substrate for cost reduction. For example, the amount of flexure Y of a second-generation mother glass-equivalent glass substrate (460 mm×365 mm) is on the order of hundreds of micrometers, and the amount of flexure X of a size-matched mask for deposition is on the order of tens of micrometers. The amount of flexure of a mask is small as compared with that of a glass substrate because the mask is very thin and is stretched at a constant tension by a frame holding it.

When a substrate and a mask for deposition with different amounts of flexure are placed over one another, the substrate first touches the mask at its center and then in its outer areas as illustrated in FIG. 7B. It is after the two components come into complete contact as illustrated in FIG. 7C that the film is deposited. During this process, the two components often lose their alignment in the direction parallel to the surface of the substrate because of the difference in flexural curvature. Such a difference in flexural curvature also makes it more likely that a dark spot, particularly one caused by rubbing with the mask, occurs at the center of the substrate.

The light emitter according to an aspect of the invention can be produced without contact between its substrate and a mask because the projections serve as spacers. For this purpose, and given the fact that most of contaminants typically found in clean rooms for the manufacture of semiconductor devices or similar are particles with diameters of 1 μm or less, the height of the projections can be 1.0 μm or more, preferably 2.0 μm or more and 10 μm or less. This limits the contact between the emission elements and the mask and reduces the occurrence of dark spots.

It should be understood that although FIGS. 7A to 7C illustrate a case where the substrate faces down during film formation, a similar method yields a highly reliable organic light emitter in an upside down case, too, in which the substrate faces up with the mask thereon during film formation.

### (2) Second Production Method

This section presents another method for the production of the organic light emitter, only describing differences from the first production method.

A pixel separator 23 as a layer of an organic insulator, such as polyimide or polyacrylate, is formed on the passivator 22 on which the first electrode 25 has been formed. These hygroscopic resins may be dehydrated through a thorough baking in vacuum beforehand if they are used in the organic layer 26.

### Cutting a Mother Glass

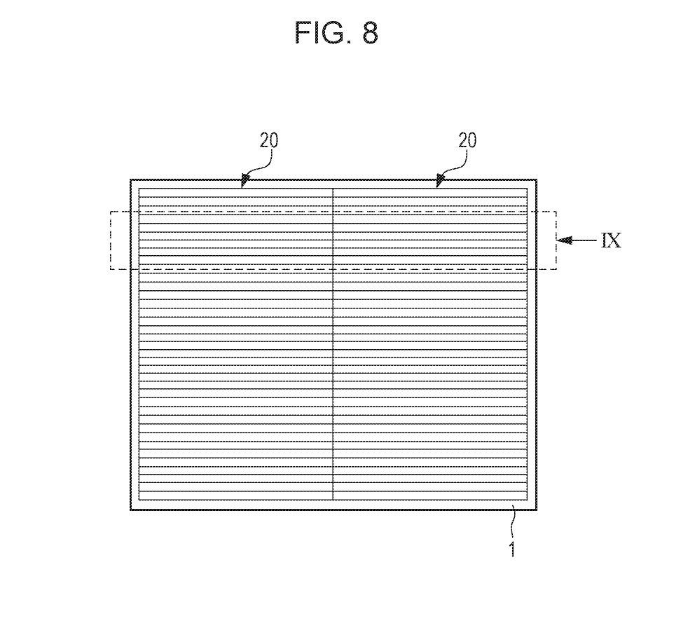

FIG. 8 illustrates a case where several elongated substrates are cut out from a single mother glass. Batch production of multiple light emitters on a single mother glass involves cutting out the individual light emitters using blade dicing, laser abrasion dicing, or similar after the formation of an inorganic seal.

It is possible to produce multiple elongated light emitters 20 (219 mm×4.7 mm) in a batch on a second-generation mother glass substrate (460 mm×365 mm). For example, a dense array of 69 rows and 2 columns formed in the middle of the mother glass substrate like the arrangement illustrated in FIG. 8 yields 138 light emitters 20. Since the mother glass substrate may come into contact with the support for the substrate at its peripheral edge while being handled, the light emitters may be arranged densely in the center of the substrate wherever possible. The light emitters can be used as an exposure light source in electrophotographic image formation systems.

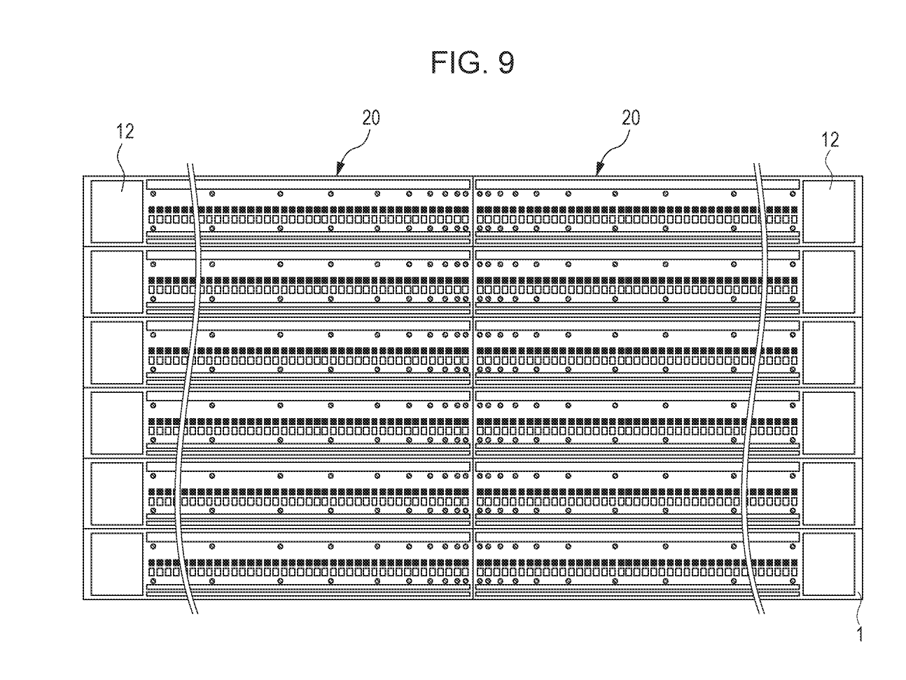

FIG. 9 is an enlarged view of area IX in FIG. 8. This area includes twelve light emitters arranged in an array of six rows and two columns. In this arrangement, the light emitters are in two columns in such a manner that the bonding pads 12 are located at the peripheral edge of the mother glass substrate, rather than in the middle. Forming the organic layer to the peripheral edge of the substrate can result in inconsistent thickness of this layer across the finished light emitters. This inconsistency can be avoided by placing bonding pads at the peripheral edge, instead of forming the organic layer.

The light emitter according to an aspect of the invention has multiple projections 5 that protrude in the direction perpendicular to the surface of the substrate in relation to the second electrode 27 and are arranged in the longitudinal direction of lines of emission elements. When the mother glass substrate and a mask for deposition are placed over one another, the mask is supported by the projections in contact with them, whereas the pixel separator, the organic layer, and the second electrode are spaced from the mask.

The projections can have any height greater than that of the upper electrode. The height of the projection can be 1.0 μm or more, preferably 2 μm or more and 10 μm or less. This is based on the fact that contaminants found in clean rooms are 1 μm or smaller in size and is to ensure that when a mask for deposition approaches the substrate with such contaminants on the substrate, the mask does not come into contact with the substrate.

The light emitter according to an aspect of the invention has projections, and these projections come into contact with the mask first. Contaminants are caught by the projections, with only limited adhesion to the light emitter. As a result, the occurrence of dark spots due to contaminants is reduced.

Contact of a mask for deposition and the projections may cause transfer of deposits on the mask to the projections. Deposits transferred to the projections can serve as starting points for cracks to grow in the seal 29 formed on the second electrode 27. A cracked seal is no longer as effective in shielding the organic EL devices 28 from the ambient atmosphere including moisture and oxygen as it has been. The use of fewer projections can be a solution to this.

Light emitters according to this embodiment can be implemented even with relatively few projections and, therefore, can be relatively free from cracking in the seal starting from projections.

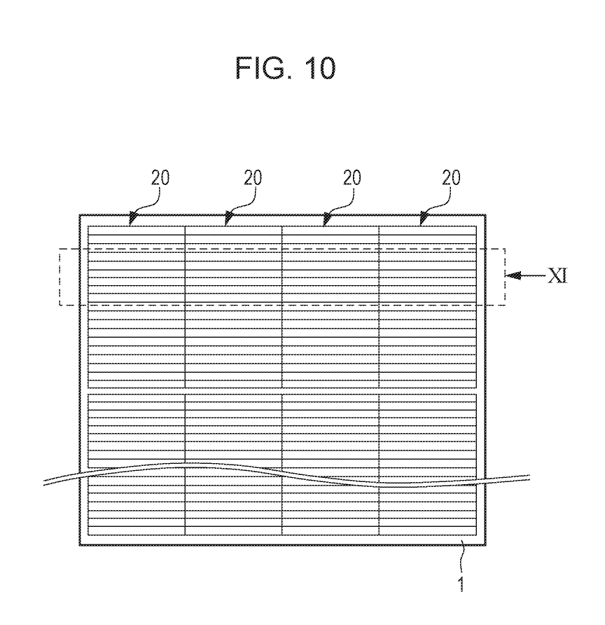

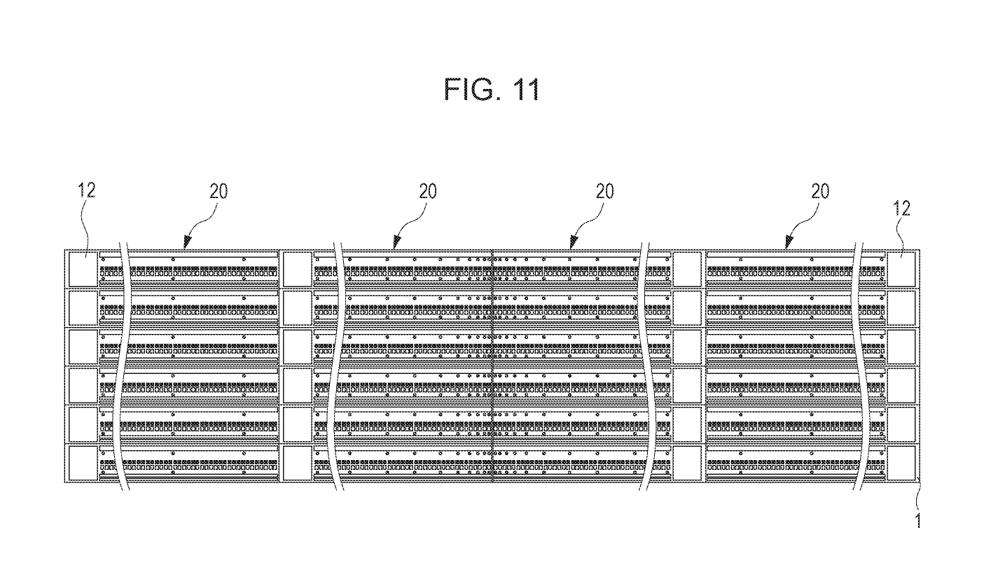

FIG. 10 illustrates batch production of multiple elongated light emitters 20 (219 mm×4.7 mm) on a 4.5-generation mother glass substrate (920 mm×730 mm). In this embodiment, the size of the mother glass substrate is different from that in the first embodiment. This difference in size makes it possible to produce 592 light emitters in a batch by arranging them in a dense array of 148 rows and 4 columns in the center of the mother glass substrate. FIG. 11 is an enlarged view of area XI in FIG. 10, including 24 light emitters arranged in an array of six rows and four columns. The outer two of the four columns of light emitters have a different arrangement pattern for projections from that of the inner two. In the outer columns of light emitters, the projections are more widely spaced than in the inner columns. This is because the mother glass substrate bends less at its peripheral edge than in the middle.

In all other respects, this embodiment is equivalent to the first embodiment. The efficient arrangement of projections in the light emitters according to this embodiment reduces the number of points of contact with external components, limiting the adhesion of contaminants. This embodiment, furthermore, provides an efficient way of manufacturing light emitters in which four columns of light emitters can be produced on a single substrate.

This embodiment is equivalent to the foregoing one except for the arrangement of the projections the light emitters have. FIG. 11 is an enlarged view of area XI in FIG. 10, including 24 light emitters arranged in an array of six rows and four columns. The spacing between projections becomes narrower toward the middle of the mother glass substrate in the outer two of the four columns of light emitters too.

In this embodiment, the arrangement and total number of projections are the same across the four columns of light emitters on the mother glass substrate.

The efficient arrangement of projections in the light emitters according to this embodiment reduces the number of points of contact with external components, limiting the adhesion of contaminants. This embodiment, furthermore, provides an efficient way of manufacturing light emitters in which four columns of light emitters can be produced on a single substrate. Even in a four-column batch production of light emitters, further reduction of the adhesion of contaminants is possible.

This embodiment is different from the foregoing ones in that the projections are not dot-shaped at least in part. Specific examples of the shapes such projections can have in their cross-sections parallel to the substrate include circular, oval, and strip-like shapes.

FIG. 12 illustrates an example of a light emitter according to this embodiment. The projections are in the shape of strips in part.

The use of strip-shaped projections leads to further reduction in the number of projections and limitation of the adhesion of contaminants.

In this aspect of the invention, the number of light emitters that can be produced on a single glass substrate increases with decreasing width of each elongated substrate. The width of each elongated substrate can be 10 mm or less, or more specifically 1 mm or more and 10 mm or less.

### Other Forms of Sealing

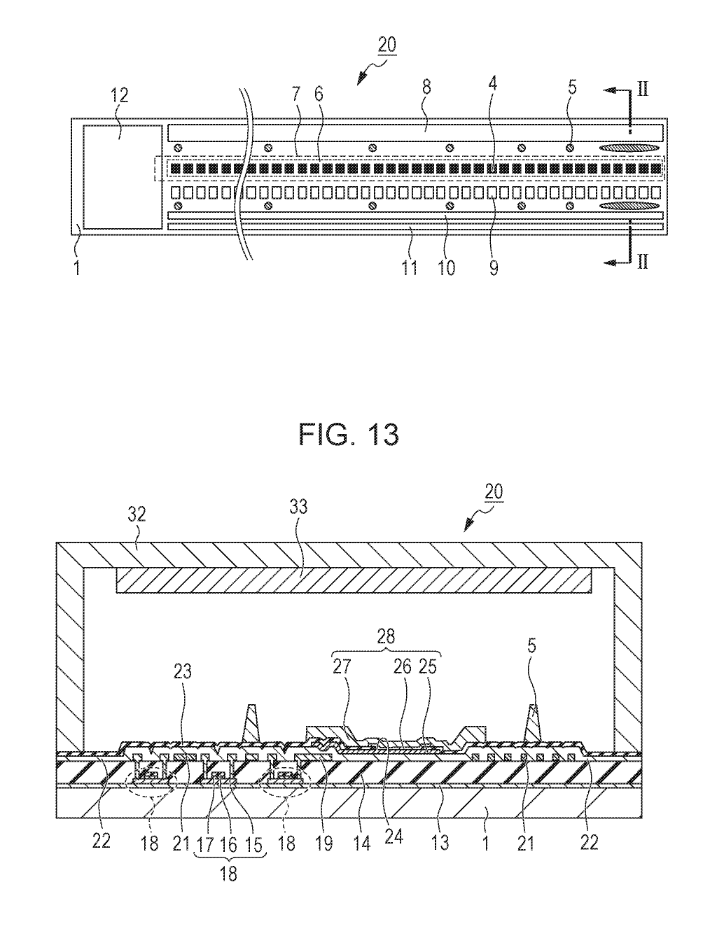

The seal is not essential for light emitters according to an aspect of the invention. FIG. 13 is a schematic cross section of a light emitter sealed with a sealing substrate 32 having a cavity. The attachment of the sealing substrate 32 is through bonding in a nitrogen atmosphere. There may be under the sealing substrate a desiccant 33 to reduce the humidity in the sealed space.

### Applications of the Organic Light Emitter

An image formation system according to an aspect of the invention has a photosensitive element, a charging section configured to charge the surface of this photosensitive element, an exposure section configured to expose the photosensitive element to light to form an electrostatic latent image, and a developer section configured to apply a developer solution to the photosensitive element to develop the electrostatic latent image formed on the surface of the photosensitive element. The exposure section of the image formation system includes an organic light emitter according to an aspect of the invention.

Organic light emitters according to an aspect of the invention can also be used as a component of exposure units configured to expose photosensitive elements to light. An example of an exposure unit that has an organic light emitter according to an aspect of the invention is one in which the organic light-emitting devices as a component of the organic light emitter according to an aspect of the invention are arranged in rows along a predetermined direction.

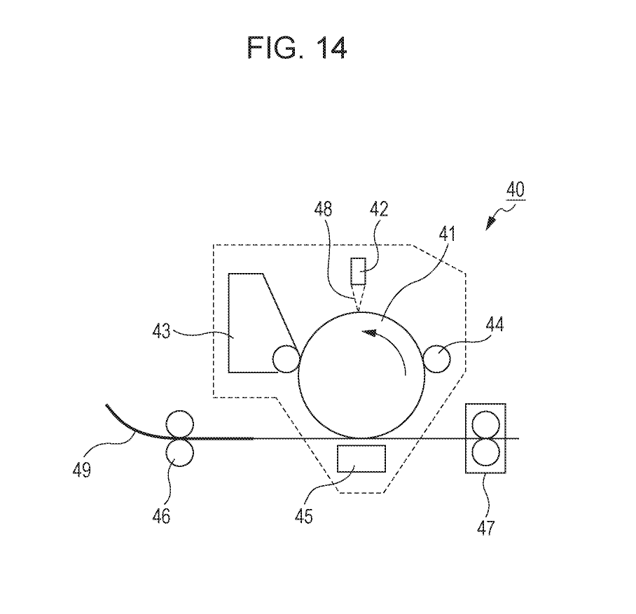

FIG. 14 is a schematic of an example of an image formation system that has an organic light emitter according to an aspect of the invention. The image formation system 40 in FIG. 14 has a photosensitive element 41, an exposure light source 42, a developer mechanism 43, a charging section 44, a transfer mechanism 45, feeding rollers 46, and a fixation mechanism 47.

The image formation system 40 in FIG. 14 emits light 48 from the exposure light source 42 toward the photosensitive element 41 to form an electrostatic latent image on the surface of the photosensitive element 41. In the image formation system 40 in FIG. 14, the exposure light source 42 is an organic light emitter according to an aspect of the invention. In the image formation system 40 in FIG. 14, furthermore, the developer mechanism 43 has some structural components such as toner. The charging section 44 is provided to charge the photosensitive element 41. The transfer mechanism 45 is provided to transfer the developed image to a record medium 49 such as paper. The feeding of the record medium 49 to the transfer mechanism 45 is done through the use of the feeding rollers 46. The fixation mechanism 47 is provided to fix the image formed on the record medium 49.

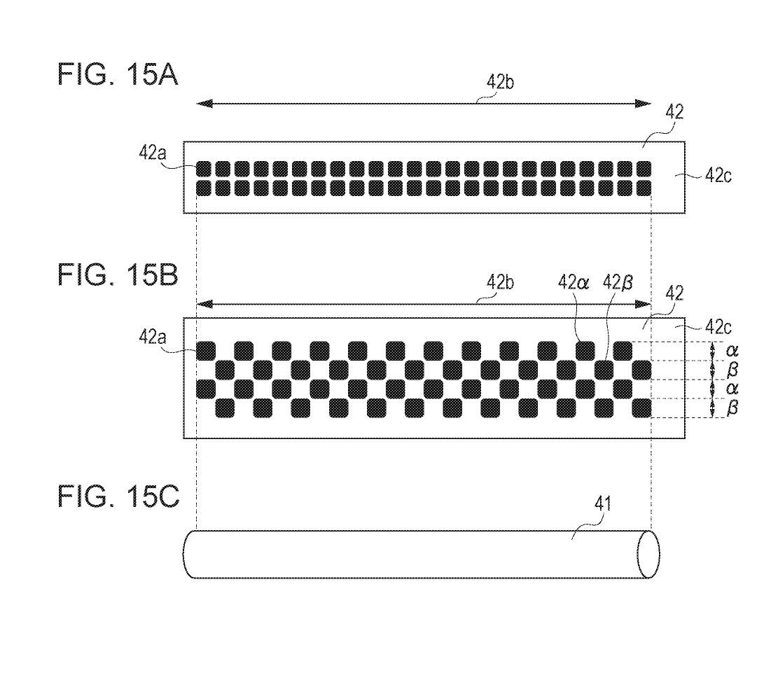

FIGS. 15A and 15B are schematic top views of specific examples of exposure light sources (exposure mechanisms) that can be used in the image formation system 40 in FIG. 14. FIG. 15C is a schematic of a specific example of a photosensitive element that can be used in the image formation system 40 in FIG. 14. There is a similarity between FIGS. 15A and 15B: the exposure light source 42 has multiple emission segments 42a, each including an organic light-emitting device, arranged in rows along the longitudinal direction of an elongated substrate 42c. The arrow 42b indicates the direction of columns, in which the emission segments 42a are arranged. The direction of columns is parallel to the rotational axis of the photosensitive element 41.

In FIG. 15A, the emission segments 42a are arranged in the direction of the axis of the photosensitive element 41. In FIG. 15B, the emission segments 42a in a first column α and those in a second column β alternate in the direction of columns. In FIG. 15B, the first column α and the second column β are in different positions in the direction of rows.

In FIG. 15B, furthermore, the first column α includes multiple emission segments 42α arranged at regular intervals, whereas the second column β has multiple emission segments 42β at the positions where the spaces between the emission segments 42α are in the first column α. This means that the exposure light source illustrated in FIG. 15B also has rows of regularly spaced emission segments.

The pattern of the emission segments (42α and 42β) constituting the exposure light source in FIG. 15B can also be described as, for example, a grid pattern, a staggered pattern, or a checkered pattern.

Organic light emitters according to an aspect of the invention therefore offer an extended and stable display of images with good quality.

### EXAMPLES

The following describes certain aspects of the invention by providing some examples. It should be understood that the process from undercoating to the formation of a pixel separator performed in the production of organic light emitters in Examples is included in an aspect of the invention, as long as it falls within the range of typical processes in the manufacture of semiconductor devices.

In the following description of Examples, some arrangements of emission elements are mentioned but non-limiting factors, such as the size of substrates, is not.

### Example 1

A light emitter was produced in accordance with the process illustrated in FIGS. 6A to 6E.

### 1-1 Start to the Formation of a Pixel Separator on a Glass Substrate (FIG. 6A)

An undercoat 13 as a layer of an inorganic insulator (silicon nitride) was formed on a glass substrate 10 using CVD. TFTs 18 including a channel 15, a gate dielectric 16, and a gate electrode 17 were formed on the undercoat 13 in the same way as in the known production of TFTs. An interlayer dielectric 14 as a layer of an inorganic insulator (silicon oxide) was formed on the undercoat 13 with the TFTs 18 thereon using CVD. The interlayer dielectric 14 was perforated with holes using photolithography and dry etching to expose the electrodes of the TFTs 18. Components including source/drain electrodes 19 and metal wiring 21 were then formed. The source/drain electrodes 19 were coupled to the TFTs 18 via the holes. A passivator 22 as a layer of an inorganic insulator (silicon oxide) was formed on the interlayer dielectric 14 with the source/drain electrodes 19, the metal wiring 21, and other components thereon using CVD. The passivator 22 was perforated with holes using photolithography and dry etching to expose the source/drain electrodes 19. A first electrode 25 was then formed using indium tin oxide (ITO), and coupled to the source/drain electrodes 19 via the holes. A pixel separator 23 as a 200-nm-thick layer of an inorganic insulator (silicon nitride) was formed on the first electrode 25 using CVD. The pixel separator 23 was patterned using photolithography and dry etching to create openings 24 that defined emission regions measuring 40 μm by 40 μm.

The total number of emission elements on the substrate was 500, and they were arranged in a row (n=1, m=500). The substrate was dehydrated through a backing at approximately 250° C. before the formation of an organic layer (described hereinafter).

### 1-2 Formation of Projections on the Pixel Separator (FIG. 6B)

A 2-μm-thick coating of a photosensitive resin material (polyimide) was formed on the pixel separator 23 using spin coating and photolithographically patterned to leave projections 5. The 2-μm-thick coating was patterned in the longitudinal direction 2 of the substrate 1 in such a manner that the width in top view would be 10 μm, that the transverse distance from the middle line of the row of emission elements would be 360 μm, and that the projection pitch would be 720 μm, leaving projections 5 on the substrate 1. Their length was shorter than that covered by the emission elements. In this way, two non-segmented 2-μm-tall and 10-μm-wide projections were formed, with one on one side and one on the other side across the organic layer. The first electrode, a component of emission elements, was therefore positioned between one projection and the other.

### 1-3 Formation of an Organic Layer (FIG. 6C)

An organic layer 26 was formed through vapor deposition using a mask to cover the exposed area, in the opening 24 created in the pixel separator 23, of the first electrode 25. During this process, the mask was in complete contact so that the organic layer 26 would be formed within a predetermined area. The organic layer was composed of a hole injection layer, a hole transport layer, an electron blocking layer, an emission layer, a hole blocking layer, an electron transport layer, and an electron injection layer deposited in this order. All materials in the individual layers were known and commercially available. The emission layer was configured to emit light in red in order to match the wavelengths of light that the photosensitive material reacts to.

### 1-4 Formation of an Upper Electrode (FIG. 6D)

A second electrode 27 was formed to cover the organic layer 26. The second electrode 27 was a 200-μm-thick film of aluminum and was formed within a predetermined area through vacuum deposition using a mask. The transverse width of the second electrode was 600 μm, and its middle line was aligned with the middle line of the row of emission elements. As a result, the second electrode 27 was spaced from the projections 5 by at least 2 μm.

### 1-5 Formation of a Seal (FIG. 6E)

A seal 29 as a 2-μm-thick layer of silicon nitride was formed on the entire surface using CVD. In this example, the pixel separator 23 and the seal 29 were in contact with each other.

A bonding pad 22 was exposed through photolithography and dry etching and connected to an external circuit. In this way, an organic light emitter 20 was obtained.

### Example 2

A light emitter was produced as in Example 1 except that the pixel separator was formed from an organic insulator.

A change was made to the formation of a pixel separator on a glass substrate (1-1; FIG. 6A) in Example 1: After the formation of the first electrode 25, a pixel separator 23 as a 200-nm-thick layer of an organic insulator (polyimide) was formed using spin coating. The pixel separator 23 was photolithographically patterned to create openings 24 that defined emission regions measuring 40 μm by 40 μm. In this example, the pixel separator 23, formed from an organic insulator, and the seal 29 were in contact with each other.

### Example 3

The procedure in Example 2 was repeated, except in the formation of projections on a pixel separator (1-2; FIG. 6B): A 5-μm-thick coating of a photosensitive resin material (polyimide) was formed on the pixel separator 23 using spin coating and photolithographically patterned to leave projections 5. The 5-μm-thick coating was patterned in the longitudinal direction 2 of the substrate 1 in such a manner that the width in top view would be 15 μm, that the transverse distance from the middle line of the row of emission elements would be 400 μm, and that the projection pitch would be 800 μm. In this way, two non-segmented 5-μm-tall and 15-μm-wide projections were formed.

### Example 4

A light emitter was produced in the same way as in Example 2, except in the formation of projections on a pixel separator (1-2; FIG. 6B): The length of the projections formed on the substrate 1 was longer than that covered by the emission elements.

### Example 5

A light emitter was produced in the same way as in Example 2, except in the formation of projections on a pixel separator (1-2; FIG. 6B): The length of the projections formed on the substrate 1 was longer than that of the organic layer subsequently formed.

### Example 6

A light emitter was produced in the same way as in Example 2, except in the formation of projections on a pixel separator (1-2; FIG. 6B): The longitudinal length of the projections formed on the substrate 1 was longer than that of the second electrode 27 subsequently formed.

### Example 7

A light emitter was produced in the same way as in Example 2, except in the formation of a pixel separator on a glass substrate (1-1; FIG. 6A): The openings 24 that defined emission regions measuring 40 μm by 40 μm were created in a staggered arrangement. The total number of emission elements was 500, and their arrangement was n=1 and m=500. The width of the row of emission elements was therefore 80 μm. Thus, in the formation of the projections (FIG. 6B), the patterning in the longitudinal direction 2 of the substrate 1 was in such a manner that the transverse distance from the projections 5 to the middle line of the row of emission elements would be 380 μm, and that the projection pitch would be 760 μm. The formation of an upper electrode (1-4; FIG. 6D) was in such a manner that the width of the upper electrode would be 640 μm.

### Example 8

A change was made to the formation of a pixel separator on a glass substrate (FIG. 6A) and to the formation of an upper electrode (FIG. 6D) in Example 2: The first electrode was a multilayer reflective electrode that had ITO, silver (Ag), and ITO layers, and the second electrode was a film of indium zinc oxide formed using sputtering.

The organic light emitter obtained in this example was in the top emission structure, a structure in which light is taken out from the sealed side. Except for these, the same procedure as in Example 2 was repeated to produce a light emitter.

### Example 9

A light emitter was produced in the same way as in Example 8, except that the substrate in Example 8 was changed to a silicon substrate. The organic light emitter obtained in this example, too, was in the top emission structure, a structure in which light is taken out from the sealed side.

### Example 10

The procedure in Example 1 was repeated, except in the formation of projections on a pixel separator (FIG. 6B): A 5-μm-thick coating of a photosensitive resin material (polyimide) was formed on the pixel separator 23 using spin coating and photolithographically patterned to leave projections 5. The 5-μm-thick coating was patterned in the longitudinal direction 2 of the substrate 1 in such a manner that the width in top view would be 15 μm, that the transverse distance from the middle line of the row of emission elements would be 400 μm, and that the projection pitch would be 800 μm. In this way, two non-segmented 5-μm-tall and 15-μm-wide projections were formed.

### Comparative Examples 1 and 2

The procedures in Examples 1 and 2, respectively, were repeated except that no projections were formed.

### Comparative Example 3

In this comparative example, the light emitter had projections but not spaced from the second electrode.

In the formation of projections on a pixel separator (1-2; FIG. 6B), the patterning in the longitudinal direction 2 of the substrate 1 was in such a manner that the transverse distance from the projections 5 to the middle line of the row of emission elements would be 360 μm, and that the projection pitch would be 720 μm. The formation of an upper electrode (1-4; FIG. 6D) was in such a manner that the transverse width of the second electrode would be 720 μm.

The production of a light emitter under these conditions was tried five times, but in all attempts, the second electrode 27 overlapped the projections 5.

### Comparative Example 4

In this comparative example, too, the light emitter had projections but in contact with the second electrode.

An organic light emitter was produced in the same way as in Comparative Example 3, except that the organic layer 26 was covered with the second electrode 27.

### Reference Example 1

In this reference example, the relationship among the projection pitch, the projection width, and the second electrode width did not satisfy formula (1). In the formation of projections on a pixel separator (1-2; FIG. 6B), the patterning in the longitudinal direction 2 of the substrate 1 was in such a manner that the transverse distance from the projections 5 to the middle line of the row of emission elements would be 360 μm, and that the projection pitch would be 720 μm. The formation of an upper electrode (1-4; FIG. 6D) was in such a manner that the width of the second electrode would be 670 μm. The projections were non-segmented, measuring 5 μm tall and 15 μm wide.

Failure to satisfy formula (1) caused the projections and the second electrode to overlap in some cases.

The production of a light emitter under the above conditions was attempted five times, but in three attempts, the second electrode 27 overlapped the projections 5. In the production of light emitters, satisfying formula (1) can be a solution to this.

### Reliability Study

The organic light emitters produced in Examples and Comparative Examples were studied as follows. The light emitters in Examples 1 to 10 were produced five times each, and in all of these light emitters, the second electrode and the projections were spaced from each other.

Light Emission after Mounting

The light emitters in Examples 1 to 10 were cut out from a mother glass and mounted in a predetermined casing. The projections 5, formed as a protector, protected the emission regions, and any damage associated with the mounting operation was confined to the projections 5, not involving the second electrode 27. Since the projections 5 and the second electrode 27 were spaced from each other, the emission elements were not reached by damaging gases, such as moisture and oxygen, penetrating through seal defects that occurred near the projections.

The emission elements were also protected from similar damage caused by contaminants that adhered to the projections during production. The projections 5 defended the finished light emitters from fatal flaws, making the light emitters reliable for extended periods.

The devices produced in Comparative Examples 1 and 2 were not as reliable. These devices experienced defects that caused flaws that grew to reach the emission elements.

### Storage Under High-Temperature and High-Humidity Conditions

The light emitters were stored at 85° C. and 85% RH. The light emitters in Examples 1 to 10 successfully emitted light even after 1000 hours of storage.

The light emitters in Comparative Examples 1 and 2 had seal defects at the edge of the organic layer and the upper electrode caused by contaminants transferred from a mask to the substrate during film formation, and these defects had increased the area of non-emission regions. In Comparative Example 3, three emitters in which the second electrode overlapped the projections 5 allowed moisture to seep thereinto through seal defects caused by contaminants on the projections. The moisture permeated the structure between the second electrode 27 and the substrate and reached the emission elements, leading to poor light emission. In Comparative Example 4, all emitters allowed moisture to seep thereinto through seal defects caused by contaminants on the projections 5. The moisture permeated the structure between the second electrode 27 and the substrate and reached the emission elements, leading to poor light emission. In Reference Example 1, moisture seeped through seal defects caused by contaminants on the projections 5. The moisture penetrated the organic layer 26 and reached the emission elements, leading to poor light emission.

The light emitters produced in Examples, in which the organic layer 26 was covered with the second electrode 27 to reduce damage to the emission elements associated with the penetration of moisture and oxygen, were found to be reliable.

An aspect of the invention provides a highly reliable light emitter. This light emitter has projections and an upper electrode spaced from each other, and this structure limits the formation of ways in for moisture or other contaminants to reach the organic EL devices in the light emitter.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-079478, filed Apr. 8, 2015, and Japanese Patent Application No. 2015-106772, filed May 26, 2015, which are hereby incorporated by reference herein in their entirety.

What is claimed is:

1. A light emitter comprising:
a substrate;
a plurality of emission elements on the substrate,
wherein the emission elements include a first electrode, an organic layer, and a second electrode in this order from a substrate side, and
wherein the organic layer stretches over one of the emission elements and a next one in a first direction of the substrate; and
a plurality of projections on the substrate, each of the projections located adjacent to each of the emission elements in a second direction of the substrate,
wherein the emission elements are located between one of the projections and another,
wherein the projections are higher than the second electrode with respect to a principal surface of the substrate, and
wherein the projections and the second electrode are spaced from each other.

2. The light emitter according to claim 1, wherein the projections and the second electrode are at least 2 μm spaced from each other in the second direction of the substrate.

3. The light emitter according to claim 1, wherein in the first direction of the substrate, one of the projections and another are irregularly spaced.

4. The light emitter according to claim 3, wherein in the first direction of the substrate, one of the projections and another are more widely spaced at one end of the substrate than at the other end.

5. The light emitter according to claim 1, wherein the projections and the second electrode are arranged to satisfy formula (1):
a distance between a middle of one of the projections and a middle of a next one−a width of the projections in the second direction of the substrate−a width of the second electrode in the second direction of the substrate≧105 μm (1).

6. The light emitter according to claim 1, wherein at least one of the plurality of projections is an elongated projection that extends in the first direction of the substrate.

7. The light emitter according to claim 1, wherein the projections are longer than the organic layer in the first direction.

8. The light emitter according to claim 1, wherein a surface of the projections opposite the substrate is at least 2.0 μm away from the substrate.

9. The light emitter according to claim 1, wherein the projections contain a photosensitive resin.

10. The light emitter according to claim 1, wherein the projections have a circular, oval, or strip-like shape in a cross-section thereof parallel to the substrate.

11. The light emitter according to claim 1, further comprising wiring coupled to the second electrode, wherein the wiring is all along one side of the substrate.

12. The light emitter according to claim 1, further comprising a seal on the second electrode, wherein the seal contains at least one of silicon oxide, silicon nitride, silicon oxynitride, and an aluminum oxide.

13. The light emitter according to claim 1, wherein the plurality of emission elements are arranged in an array of n rows and m columns, with n≦4 and 100≦m.

14. The light emitter according to claim 1, wherein the substrate has a length of 1 mm or more and 10 mm or less in the second direction.

15. The light emitter according to claim 13,
wherein the plurality of emission elements are arranged in a plurality of rows,
wherein in a first row of the plurality of rows, the emission elements are spaced from each other in a direction of the rows, and
wherein in another row, the emission elements are at positions where spaces between one of the emission elements and another are in the first row.

16. An image formation system comprising:
a photosensitive element;
an exposure section configured to expose the photosensitive element to light;
a charging section configured to charge the photosensitive element; and
a developer section configured to apply a developer solution to the photosensitive element,
wherein the exposure section includes a light emitter according to claim 1, and the plurality of emission elements the light emitter has are arranged in a longitudinal direction of the photosensitive element.

17. An exposure unit configured to expose a photosensitive element to light, comprising:
a light emitter according to claim 1, wherein
the plurality of emission elements the light emitter has are arranged in a longitudinal direction of the photosensitive element.
